(19) United States
(12) Patent Application Publication
(10) Pub. No.: US 2025/0081405 A1
(43) Pub. Date: Mar. 6, 2025

(54) Implementation of Two-Phase Cold Plate Loops with Design Features to Optimize Thermofluidic Performance in Space Constrained Computer Architectures

(71) Applicant: Seguente, Inc., Melbourne, FL (US)

(72) Inventors: Ryan Enright, Berkeley Heights, NJ (US); Raffaele Luca Amalfi, Melbourne, FL (US); John Kim, Orlando, FL (US); Alexei Tyryshkin, Palm Bay, FL (US)

(21) Appl. No.: 18/825,750

(22) Filed: Sep. 5, 2024

Related U.S. Application Data
(60) Provisional application No. 63/536,792, filed on Sep. 6, 2023.

(51) Int. Cl. H05K 7/20

(52) U.S. Cl. CPC H05K 7/20809; H05K 7/20309; H05K 7/20327

(57) ABSTRACT

Arrangements, sub-systems, devices and methods for providing cooling to hardware components, and more specifically to server cold plate loop (CPL) sub-systems, devices and methods for thermal management of hardware in computer server racks and related equipment in computer data centers.

### CROSS REFERENCE TO RELATED APPLICATION

This application claims the benefit of priority to U.S. Provisional Application Ser. No. 63/536,792 filed Sep. 6, 2023, the entire disclosure of which is incorporated herein by specific reference thereto.

### FIELD OF INVENTION

This invention relates to sub-systems, devices and methods for providing cooling to hardware components, and more specifically to server cold plate loop sub-systems, devices and methods for thermal management of hardware in computer server racks and related equipment in computer data centres.

### BACKGROUND AND PRIOR ART

The seismic shift towards digitization across virtually all industries is resulting in urgent mandates to develop next-generation information and communication technologies (ICT) to address transmission, orchestration, storage, and processing of evermore increasing volume of data. It is widely expected that, due to the higher power dissipation of new generations of hardware components, e.g., CPUs (central processing units) and GPUs (graphical processing units).

Traditional air-based thermal management solutions will face significant challenges. Specifically, air-cooling technologies will likely reach physical limits for power dissipation in prevailing hardware form factors and their decreasing energy efficiency is a growing concern for operators.

Most data centers and telecom installations are designed for and still operate with air-cooling technologies, and their energy consumption to cool hardware equipment is on average approximately 40% of the total energy consumption.

With growing awareness of social responsibility to combat climate change, there is a global consensus for action to improve energy efficiency and reduce carbon emissions across all industry. Hence, it is extremely important the development of a novel high-efficiency cooling technology, which will meet these requirements and can be widely adopted. Two-phase cooling technologies provide excellent key metrics, e.g., heat density, efficiency, reliability, etc., and represent a viable, long-term solution with regards to hardware densifications and thermal performance required by next-generation telecommunications and computing platforms.

In both actively pumped and passive gravity-driven two-phase thermal management systems, the liquid coolant is routed via conduits into the server to one or more evaporators and undergoes boiling to cool the heat generating components. The resulting two-phase mixture (liquid+vapor) is then routed back out of the server to a heat rejection unit that converts the two-phase mixture back to, or mostly back to, liquid to repeat the cycle.

In general, server architectures present as a highly constrained design space for fluid routing which has an impact on the size and layout of fluid conduits as well as evaporator design. These constraints require the designer to consider the combination of the fluid conduit routing and evaporators as a sub-system of the cooling system, collectively termed the cold-plate loop (CPL) here, to be optimized in order to meet the required performance goals in terms of evaporator thermal performance and overall CPL pressure drop.

This invention disclosure details direct liquid cooling (DLC) flow distribution architectures at the server level addressing multiple heat sources to ensure optimal operation of two-phase cooling technologies overcoming flow instabilities, flow maldistribution and facilitates maximum IT hardware availability.

U.S. Pat. No. 7,331,378 to Bhatti, which is incorporated by reference in its' entirety, discloses a microchannel heatsink for flowing coolant into inlet manifold channels extending into an inlet edge of a manifold, where the flow is forced downward into parallel and spaced microchannels extending across the manifold channels and re-directing the coolant up into and out of outlet manifold channels extending into an outlet edge of the manifold and interleaved with the inlet manifold channels. The heatsink provides for maintaining a base-width of the microchannels in the range of forty microns to one hundred microns, maintaining a base height of the microchannels in the range of two hundred microns to four hundred microns, maintaining a manifold height through of the manifold channels in the range of one thousand microns to three thousand microns, and maintaining a manifold-width of the manifold channels in the range of three hundred and fifty microns to one thousand microns.

This heat sink is for transferring heat from a heat source to a coolant fluid comprising parallel microchannels overlaid transversely across by manifold channels that directs the fluid flow from the inlet plenum side down from the manifold channels into the microchannels and back up into manifold channels fluidically connected to the outlet plenum.

U.S. Pat. No. 9,603,284 to Lyon, which is incorporated by reference in its' entirety, discloses a fluid heat exchanger that can define a plurality of microchannels each having a first end and an opposite end and extending substantially parallel with each other microchannel. Each microchannel can define a continuous channel flow path between its respective first end and opposite end. A fluid inlet opening for the plurality of microchannels can be positioned between the microchannel first and opposite ends. A first fluid outlet opening from the plurality of microchannels can be positioned adjacent each of the microchannel first ends. An opposite fluid outlet opening from the plurality of microchannels can be positioned adjacent each of the microchannel opposite ends such that a flow of heat transfer fluid passing into the plurality of microchannels flows along the full length of each of the plurality of microchannels outwardly from the fluid inlet opening. Related methods are disclosed.

Lyon '284 describes the design of a heat exchanger for cooling an electronic device that distributes the cooling fluid in a diverging split flow arrangement to microchannels to reduce the flow resistance and attendant pumping power. The flow path is defined by a plate positioned over the plurality of walls and partially closing off the plurality of microchannels and incorporating a seal that separates the inlet and outlet fluid flows. The plate opening at the flow exit end of the microchannel is non-uniform having a larger opening at the central location of the plate compared to the edge of the microchannel array.

U.S. Pat. No. 9,157,687 to Schon, which is incorporated by reference in its'entirety, describes a heat pipe that can include a microchannel heat exchanger at the heat absorbing end and another heat exchanger which is optionally also a microchannel heat exchanger at the heat sink end, with one or more pipes flowably connecting the two ends for transporting liquid working fluid to the head absorber and vaporized working fluid to the heat sink. The heat pipes may be used to cool electronic devices with rejection of heat outside an enclosure, and optionally outside a room, containing the electronic devices. The heat pipes may be used to cool photovoltaic or solar collection devices with rejection of heat to ambient air at a distance removed from the photovoltaic devices. Heat pipe systems are disclosed wherein the working fluid is a hydrofluorocarbon or a mono-chlorinated hydrofluoroalkane having a normal boiling point in a range from 10° C. to 80° C.

This heat pipe describes a cooling loop incorporating microchannel heat exchangers functioning as evaporators and condensers in a simple fluidic loop. There is no discussion of the specific challenges associated with deploying cooling loops in servers.

U.S. Pat. No. 10,288,330 to Schon, which is incorporated by reference in its' entirety discloses a converging split-flow microchannel evaporator. It includes a conductive contact surface to mate to a surface to be cooled, with a core mounted in thermal connection with the conductive surface that defines at least one layer of microchannels. Within the core, one inlet restriction restricts the flow into each microchannel in a first group of the microchannels, and another restricts the flow into each microchannel in a second group. A centrally located fluid outlet receives the flows from opposite ends of the microchannels in the two groups. A check valve can be provided to help ensure ready startup without reverse flow.

Schon '330 focuses on a design of microchannel evaporator incorporating a converging split flow design to reduce pressure drop. Restrictions are incorporated in the body of the structure defining the inlet of the microchannels. A check valve is included upstream of the first and second inlets to help ensure ready startup without reverse flow wherein the check valve includes a Tesla diode. However, no consideration is given for the implementation of the evaporators into a CP (cold plate loop) within the server architecture or the configuration of the flow delivery to the evaporator.

U.S. Pat. No. 9,854,715 to Shedd, which is incorporated by reference in its'entirety, disclose a flexible two-phase cooling apparatus for cooling microprocessors in servers can include a primary cooling loop, a first and a second bypass. The primary cooling loop can include a reservoir, a pump, an inlet manifold, an outlet manifold, and flexible cooling lines extending from the inlet manifold to the outlet manifold. The flexible cooling lines can be routable within server housings and can be fluidically connected to two or more series-connected heatsink modules that are mountable on microprocessors of the servers.

The flexible cooling lines can be configured to transport low-pressure, two-phase dielectric coolant. The first bypass can include a first pressure regulator configured to regulate a first bypass flow of coolant through the first bypass. The second bypass can include a second pressure regulator configured to regulate a second bypass flow of coolant through the second bypass.

Shedd '715 discloses a two-phase cooling system utilizing flexible cooling lines to facilitate routing inside the server. A serial flow configuration is defined, and pressure regulator devices are used to manage the pressure drop across the evaporators inside the server. The evaporator design incorporates a plurality of orifices that direct jet stream of coolant against the heated surface of the evaporator in the outlet chamber for the flow.

U.S. Pat. No. 9,941,250 to Brunschwiler, which is incorporated by reference in its' entirety, discloses a package structure to implement two-phase cooling that includes a chip stack disposed on a substrate, and a package lid that encloses the chip stack. The chip stack includes a plurality of conjoined chips, a central inlet manifold formed through a central region of the chip stack, and a peripheral outlet manifold. The central input manifold includes inlet nozzles to fed liquid coolant into flow cavities formed between adjacent conjoined chips. The peripheral outlet manifold outputs heated liquid and vapor from the flow cavities. The package lid includes a central coolant supply inlet aligned to the central inlet manifold, and a peripheral liquid-vapor outlet to output heated liquid and vapor that exits from the peripheral outlet manifold. Guiding walls may be included in the flow cavities to guide a flow of liquid and vapor, and the guiding walls can be arranged to form radial flow channels that are fed by different inlet nozzles of the central inlet manifold.

Brunschwiler '250 focuses on a 3D (three dimensional) chip stack cooled by a radially flowing fluid undergoing phase change. The flow distribution to the various levels of the chip stack is in a parallel configuration with an inlet restriction to each section of the multi-sectioned evaporator structure at each level in the chip stack. Incorporation of this cooling device into a CPL (cold plate loop).
and the distribution of working fluid to the cooling device are not discussed.

U.S. Pat. No. 10,531,594 to Reeves, which is incorporated by reference in its' entirety, disclose a liquid cooled cold plate has a tub with an inlet port and an outlet port and a plurality of pockets recessed within a top surface of the tub. Each pocket has a peripheral opening and a ledge. The ledge is disposed inwardly and downwardly from the peripheral opening. The inlet port and outlet port are in fluid communication with the pocket via an inlet slot and an outlet slot. A plurality of cooling plates is each received by a pocket and recessed within the pocket. Each cooling plate comprises an electronics side for receiving electronics and enhanced side for cooling the cooling plate. The enhanced side of the cooling plate comprises a plurality of pins formed by micro deformation technology. The tub may be formed by extrusion.

Reeves '594 focuses on a monolithic liquid cooled heat exchanger incorporating pockets that are enclosed with a number of cooling plates incorporating extended surfaces, e.g., fins, to enhance heat transfer on one side and having the heat generating components mounted on the other side by mechanical components. The cooling plates are addressed by the cooling liquid in parallel in a symmetric U-shaped manifold configuration. The flow to each cooling plate is balanced by defining flow restricting slots into the body of the monolithic liquid cooled heat exchanger at the liquid inlet and outlet sides.

U.S. Pat. No. 11,044,835 to Chiu, which is incorporated by reference in its' entirety, disclose a server tray package includes a mother board assembly that includes a plurality of data center electronic devices.

The plurality of data center electronic devices includes at least one heat generating processor device; a vapor chamber mounted on and in conductive thermal contact with the at least one heat generating processor device. The vapor chamber includes a housing that defines an inner volume that encloses a working fluid; and a liquid cold plate assembly that includes a top portion mounted to at least one of the vapor chambers or the mother board assembly including a heat transfer member that includes an inlet port and an outlet port that are in fluid communication with a cooling liquid flow path defined through the heat transfer member and formed on a top surface of the housing of the vapor chamber.

Chiu '835 focuses primarily on the combination of a liquid cooled heatsink coupled to a vapor chamber device addressing one or more heat generating components within the server. Consideration for routing of the cooling liquid flow path is not given.

U.S. Published Patent Application 2024/0098937 to Provenziani, which is incorporated by reference in its' entirety, disclose a microchannel type evaporator suitable for cooling electronic components, which exchanger comprises a plate-like body having an external coupling surface with the electronic component to be cooled. The plate-like body internally carries an inlet manifold for a two-phase cooling fluid and an outlet manifold for said fluid downstream of the heat exchange. The inlet manifold and the outlet manifold are in fluid communication by means of a heat exchange chamber placed inside said plate-like body at said coupling surface and by means of unidirectional circulation means of the two-phase cooling fluid. The unidirectional circulation means is housed in the plate-like body and is configured to allow circulation of the liquid phase of the fluid exclusively from the outlet manifold towards the inlet manifold.

Cataldo '177 focuses primarily on controlling instabilities in two-phase evaporators by using one or more Tesla valve/diode structure incorporated into the body of the evaporator to bias the flow direction. The evaporator manifolds are separated from flow channels comprised of a metal foam structure or a plurality of ribs made in form of fins by an interposed fluid distribution means preferably shaped like a plate. It is also mentioned that at the level of server, the evaporators can be connected parallelly. However, no discussion on the balancing of the flow in this configuration is made.

Thus, the need exists for solutions to the above problems with the prior art.

### SUMMARY OF THE INVENTION

Chipsets for high-performance computer and data center applications are increasing in total thermal power dissipation and thermal power density. These chipsets can be comprised of CPU die, GPU die, HBM die stacks and/or power delivery components. For a direct liquid cooling (DLC) system, a key sub-system is the cold plate loop (CPL) which is comprised of the heat sinks/evaporators, fittings, fluid routing tubing and the interface to the system level, e.g., rack-scale, fluid circulation loop. The CPL design is subject to several requirements and constraints.

The primary requirements are that sufficient mass flow rate is provided to each evaporator with minimum pressure drop between the inlet and outlet of the CPL while avoiding flow instabilities that can arise in the heat transfer section of the evaporator. The primary constraints are related to the limited available space within the server for sizing and routing the fluid conduits which can have an impact on the flow distribution to multiple evaporators and overall CPL pressure drop. Two characteristic flow distribution options are possible; serial flow distribution whereby the fluid is routed on a singular path through each evaporator sequentially and parallel flow distribution whereby the flow is split passing through the evaporators in parallel.

A serial flow configuration is preferred as it avoids the issue of flow balancing found in parallel flow configurations. However, as server heat load increases, higher fluid mass flow rates and more pumping power are required. In two-phase cooling systems. This can impact thermal performance by increasing flow qualities and increasing in single phase flow length, both of which can have a significant negative impact on the thermal resistance of the evaporators.

Implementing a parallel flow configuration allows the designer to address the poor pressure drop scaling of serial flow configuration but introduces challenges in flow distribution and, potentially, routing additional tubing.

In two-phase cooling systems, evaporators receiving too much flow can see significant increases in thermal resistance due to increased single phase flow lengths through the evaporator. In the other extreme, evaporators receiving too little flow will experience flow qualities approaching unity leading to rapidly rising thermal resistance in the dry-out limit.

Simple scaling shows that the hydraulic power scales as N² for a serial flow configuration, where N is the number of heatsinks. For an ideal parallel flow network neglecting the contribution from the fluid routing conduits, the hydraulic power is constant with increasing N. This suggests that, as N increases, a combination of serial and parallel flow elements may be required to maintain a certain range of design pressure drop in the CPL for a given mass flow rate requirement.

However, balancing flow in parallel flow configuration can be expensive in terms of pressure drop for two-phase systems. The hydraulic resistance of the evaporator can change significantly as dissipated power and, hence, flow quality vary. This can lead to a situation where the flow balancing elements may consume a significant portion of the pressure drop budget in the CPL at the design mass flow rate. Thus, it is crucial to carefully co-design all the elements of the CPL (cold plate loop) to achieve the cooling goal for a particular server architecture.

However, a practical constraint is the need to be able to address a wide range of server architectures with the cooling technology. If the cooling technology is too specialized for a particular cooling architecture, it will limit the achievable economies of scale for the technology. Here we disclose the design and construction of two-phase CPLs that can be adapted to a range of server and processor architectures in a facile way that allows for serial, parallel and hybrid serial/parallel flow configurations to be realized in both actively pumped and passive gravity-driven systems.

Efficient extraction of heat from high power compute devices is critical for the continued scaling of IT (Information Technology) system performance. Minimizing the temperature drop from the target device to the edge of the facility is a primary goal which when achieved facilitates greater facility efficiency even in the face of more stringent constraints on maximum device temperatures.

A critical link in the thermal chain is the two-phase cooled heat sink that is conductively interfaced to the target device. An ideal two-phase heat sink achieves low thermal resistance with a minimum amount of supplied fluid while remaining stable in operation from start-up to full thermal design power (TDP).

Achieving full thermal design power (TDP) requires heat sink features that can manage pressure fluctuations that occur during the nucleation of the vapor phase while also facilitating the ideal distribution of the coolant to the heat transfer structures to optimize pressure drop, thermal resistance, and promote surface temperature uniformity in the face of non-uniform device power maps and elevated internal fluid pressure.

Further objects and advantages of this invention will be apparent from the following detailed description of the presently preferred embodiments which are illustrated schematically in the accompanying drawings.

### BRIEF DESCRIPTION OF THE FIGURES

The drawing figures depict one or more implementations in accord with the present concepts, by way of example only, not by way of limitations. In the figures, like reference numerals refer to the same or similar elements.

FIG. 1 (CPL) shows an example of a dual socket cold plate loop (CPL) implementation comprised of formed tubing in a serial flow configuration.

FIG. 2 shows the implementation of a CPL tubing arrangement where the nominally circular tubing is rolled locally to a non-circular shape.

FIG. 3 shows the implementation of flat tubing sections in the CPL.

FIG. 4 shows the implementation of the evaporator manifold fluidic interface.

FIGS. 5a, 5b, 5c, 5d and 5e shows schematics of low-profile fittings to facilitate optimized fluidic coupling between the evaporator and tubing of the cold plate loop.

FIG. 6 is a perspective view of an additional implementation of a low-profile fitting with a barb connection for polymer barrier tubing.

FIG. 7a is a perspective view of additional implementation of the CPL fitting to fluidically couple to the cold plate.

FIG. 7b is a cross-sectional view of the CPL fitting of FIG. 7a.

FIG. 8 is a perspective view of an additional implementation of the CPL fitting with barb connections.

FIG. 9 is a perspective view and cut-away view of a thin insert sheet for flow separation and control assembled into the CPL evaporator.

FIG. 10 is a perspective view of the cover plate defining the evaporator manifold with flow-guiding pin fins.

FIG. 11 shows the thin sheet insert for flow separation and control.

FIG. 12 shows an additional implementation of the thin sheet insert for flow separation and distribution with a non-uniform geometry in the inlet region.

FIG. 13 shows an additional implementation of the thin sheet insert for flow separation and distribution with capillary-scale apertures in the inlet region.

FIG. 14 shows an implementation of a composite dense/porous, thin sheet insert for flow separation and distribution with a centralized porous inlet providing for bidirectional flow in the heat transfer section.

FIG. 15 shows an implementation of a composite dense/porous, thin sheet insert for flow separation and distribution with distributed porous inlets providing for the injection of liquid flow along the flow path in the heat transfer section.

FIG. 16a shows evaporator simulation results showing dimensionless pressure drop, dimensionless temperature variation and flow quality in the heat transfer section for a single liquid inlet design.

FIG. 16b shows evaporator simulation results showing dimensionless pressure drop, dimensionless temperature variation and flow quality in the heat transfer section for a distributed inlet design.

FIG. 17a is a schematic of the porous-layer-up configuration for the composite dense/porous, thin sheet insert interfacing to the heat transfer section of the evaporator.

FIG. 17b is a schematic of the porous-layer-down configuration for the composite dense/porous, thin sheet insert interfacing to the heat transfer section of the evaporator.

FIG. 18 shows a schematic of the spatial distribution of surface roughness enhancement in the heat transfer section.

FIG. 19 shows a cross-section schematic of the evolving two-phase flow in the spatially distributed surface roughness enhanced heat transfer section.

FIG. 20 shows a schematic of a serial CPL configuration.

FIGS. 21a and 21b show simulation results for a serial CPL based on the layout shown in FIG. 20 with two evaporators.

FIG. 22 shows a schematic of a parallel CPL configuration with two evaporators.

FIG. 23 is a graph showing parallel CPL simulation results based on the layout shown in FIG. 22 with two evaporators.

FIG. 24 shows parallel CPL simulation results for asymmetric heat-loading based on the layout shown in FIG. 22.

FIG. 25 shows a parallel CPL with nested serial sections with in-server fluid distribution manifolds.

### DESCRIPTION OF THE PREFERRED EMBODIMENTS

Before explaining the disclosed embodiments of the present invention in detail it is to be understood that the invention is not limited in its applications to the details of the particular arrangements shown since the invention is capable of other embodiments. Also, the terminology used herein is for the purpose of description and not of limitation. In the Summary above and in the Detailed Description of Preferred Embodiments and in the accompanying drawings, reference is made to particular features (including method steps) of the invention. It is to be understood that the disclosure of the invention in this specification does not include all possible combinations of such particular features. For example, where a particular feature is disclosed in the context of a particular aspect or embodiment of the invention, that feature can also be used, to the extent possible, in combination with and/or in the context of other particular aspects and embodiments of the invention, and in the invention generally.

In this section, some embodiments of the invention will be described more fully with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will convey the scope of the invention to those skilled in the art. Like numbers refer to like elements throughout, and prime notation is used to indicate similar elements in alternative embodiments.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Unless otherwise specifically noted, articles depicted in the drawings are not necessarily drawn to scale.

### LIST OF ABBREVIATIONS

CPL cold plate loop
CPU central processing unit
CSA cross section area
GPU graphical processing unit
ICT Information & Communication Technology
TDP thermal design power
A listing of the components will now be described.
100 Dual socket cold plate loop (CPL) implementation.
101 evaporators
102 low profile tee or elbow fitting
103 large diameter tube
104 single phase liquid flow
200 Implementation of a CPL tubing arrangement
201, 201′ Noncircular shape
300 Implementation of flat tubing sections in CPL
302 Flat tubing design
301 slotted evaporator fitting
303 structural web element
400 Implementation of the evaporator manifold fluidic interface
401 evaporator cover plate
402 manifold shape
403 radiused internal edges of slotted ports
500 Schematics of low profile fittings
501 Long elbow design
502 profile of long elbow
503 slotted opening into elbow fitting
504 elbow
505 tee type fitting
506 cross flow conduit in the tee fitting
507 slotted opening into tee fitting
508 Fitting insert
509 shaped insert profile to sit into slotted opening of fitting
510 Flow restrictions
511 below opening
600 low profile with barb connection for polymer barrier tubing
601 long elbow design
602 barb connection
700 Additional implementation of CPL fitting to fluidically couple to cold plate
701 fitting
702 mechanical attachment
703 O-ring
800 Additional implementation of CPL fitting with barb connections
801 fitting body
802 barb connection
900 CPL evaporator embodiment
901 thin insert sheet
902 cover plate
903 manifold cavity
904 heat transfer section
1000 cover plate
1001 evaporator manifold
1002 flow guiding fin pins
1003 preferential flow paths
1100 Basic implementation of thin sheet insert for flow separation between manifolds
1101 insert corners radiused
1102 restriction openings less than registration radius
1102 registration radius
1200 Additional implementation of thin sheet insert
1201 inlet restriction profile
1300 implementation of thin sheet insert for flow separation & distribution incorporating capillary-scale apertures
1301 inlet restriction
1302 insert
1303 example holes
1400 Implementation of composite dense thin porous thin sheet for flow separation and distribution with a centralized porous inlet
1401 centralized porous insert
1402 fine mesh structure
1403 indicating bidirectional flow
1404 first outlet
1405 second outlet
1406 dense layer of composite dense/porous thin sheet insert
1407 porous layer of composite dense/porous thin sheet insert
1500 Implementation of a composite dense/porous, thin sheet insert for flow separation and distribution with distributed porous inlets
1501 distributed porous inlets
1502 small scale flow apertures
1503 first flow inlet
1504 distance
1505 second flow inlet
1506 different separation distance
1507 widths
1508 different opening width
1509 thin sheet insert
1510 two phase flow
1700a side view schematic of the porous layer-up configuration for composite dense/porous thin sheet insert
1701 evaporator base
1702 heat transfer structures
1703 woven mesh
1704 insert
1700b side view alternative schematic of the porous layer-up configuration for composite dense/porous thin sheet insert
1800 Spatial distribution of surface roughness enhancement in heat transfer section
1801 heat transfer section
1802 outlet
1803 structured region of heat transfer section optimized for nucleation
1804 structured region of heat transfer section optimized for capillary wicking
1900 cross section of heat transfer section
1901 heat transfer section
1902 thin sheet insert
1903 imposed heat load
1904 fins, pins or other extended surface structures
1905 working fluid
1906 roughened surface
1907 vapor phase
1908 slug flow regime
1909 liquid thin film between vapor and wall characteristic of the annular flow regime
1910 liquid wicking path
2000 schematic of serial CPL configuration
2001 server
2002 insert
2003 restriction defined by the insert
2004 larger inert defined opening
2005 divider in cover plate
2006 entrance to the heat transfer section
2007 large opening
2008 two phase flow exits server
2009 keep out boundary inside the server
2200 schematic of parallel CPL configuration with two evaporators
2201 working fluid entering server
2202 slotted tee fitting
2203 insert
2204 inlet restriction
2205 larger opening exit
2206 divider in cover plate
2207 slotted tee
2208 inlet restriction
2209 slotted elbow fitting
2210 larger opening exit
2211 return conduit exiting server
2500 parallel CPL with nested serial sections with in-server fluid distribution manifolds for a 12 socket server
2501 entering conduit
2502 inlet distribution manifold
2503 four conduits in parallel
2504 slotted elbow fitting
2505 inlet restriction
2506 insert
2507 larger opening exit in insert
2508 elbow fitting
2509 large cross sectional flow area conduit
2510 large exit opening
2511 return collection manifold
2512 server exit conduit

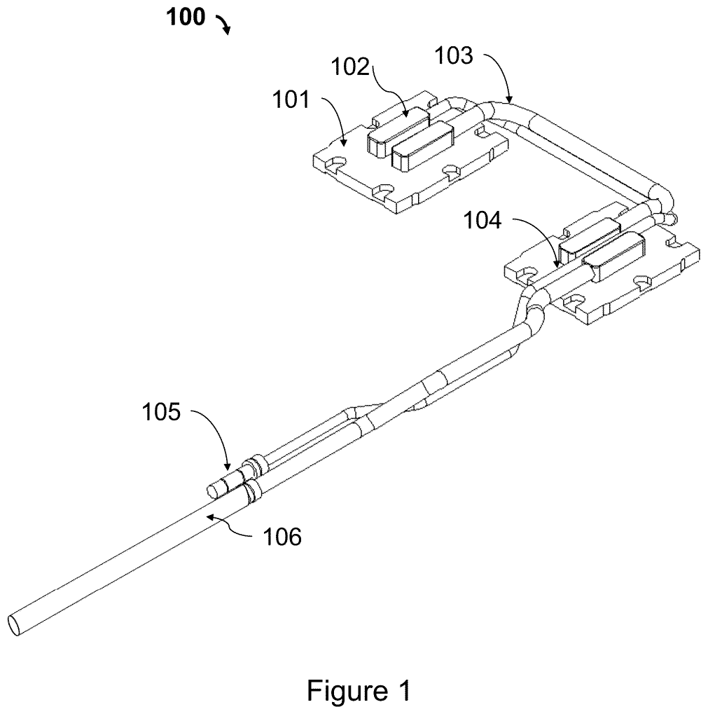

FIG. 1 shows an example of a dual socket cold plate loop (CPL) implementation 100 comprised of formed tubing in a serial flow configuration. The evaporators 101 are coupled fluidically to the CPL tubing via a low-profile tee or elbow fitting 102. The tubing routing is defined such that the single-phase liquid flow 104 is routed to the furthest evaporator from the fluid entry point into the server and flows back in two-phase after absorbing heat from the evaporator in a larger diameter tube 103 to minimize the two-phase flow length and, hence, overall hydraulic resistance/pressure drop. The CPL is interfaced to flexible polymer barrier tubes 106 via refrigerant-grade barb fittings 105 (flexible polymer barrier tube removed for clarity).

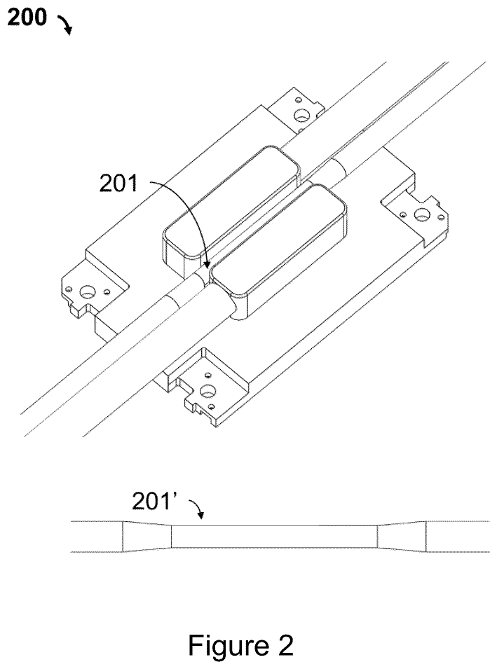

FIG. 2 shows the implementation of a CPL tubing arrangement 200 where the nominally circular tubing is rolled locally to a non-circular shape 201, 201′ to address a routing constraint between the two fittings of the evaporator. 201′ shows a top view of the locally rolled tube showing the reduced with of the tubing.

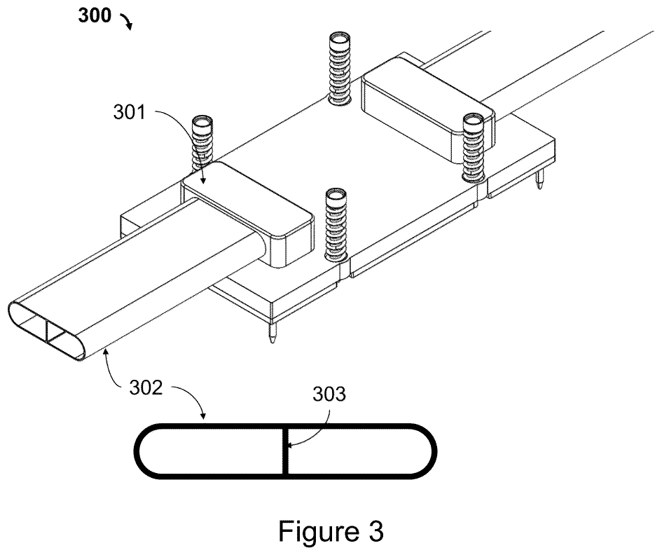

FIG. 3 shows the implementation 300 of flat tubing sections in the CPL. A flat tubing design 302 connects to a slotted evaporator fitting 301 to increase the available cross sectional flow area to minimize pressure drop in the CPL. The flat tube can be extruded to include a structural web element 303 to mechanically reinforce the flat tube that is subject to internal pressure.

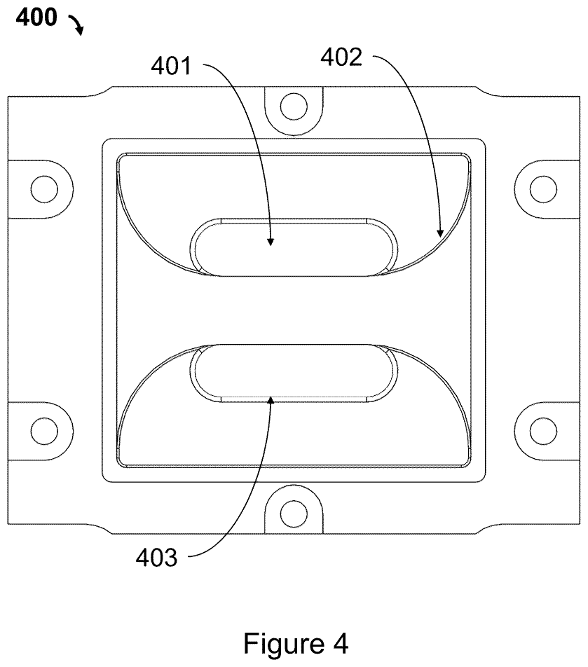

FIG. 4 shows the implementation of the evaporator manifold fluidic interface 400. Slot openings are defined in the evaporator cover plate 401 to maximize cross sectional flow area and provide for reduced pressure drop as the working fluid flows into and out of the evaporator. The manifold is shaped 402 to further optimize the flow transition while also providing mechanical reinforcement to the overall evaporator structure. The internal edges of the slotted ports in the cover plate are radiused 403 to minimize secondary pressure losses

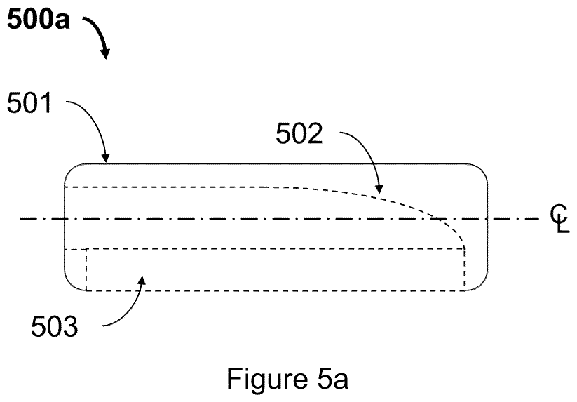

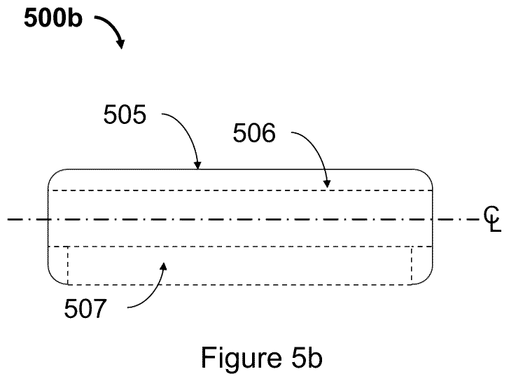

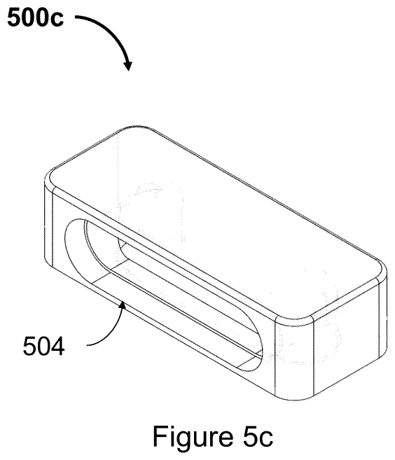

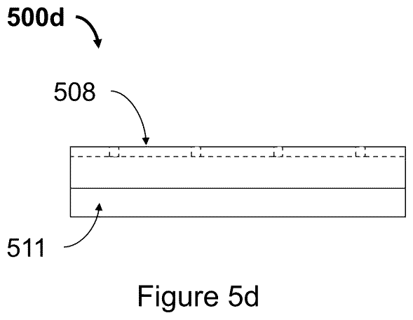

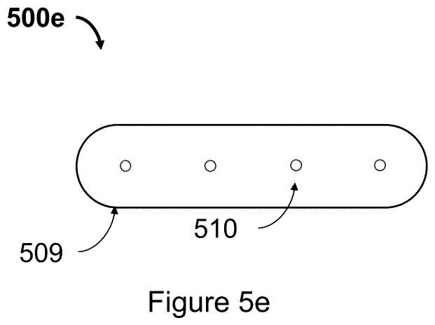

FIGS. 5a, 5b, 5c, 5d and 5e shows schematics 500 of low-profile fittings to facilitate optimized fluidic coupling between the evaporator and tubing of the cold plate loop. In FIG. 5a, a long elbow design 501 transitions the flow with a profile 502 to enhance flow distribution while minimizing pressure drop from a tube to the slotted opening 507 (shown in FIG. 5b) compatible with the cover plate manifold. For non-circular tubes, the elbow 504 (FIG. 5c) can be defined to accept the profile of the flat tube along the long edge of the fitting. A tee type fitting 505 (FIG. 5b) can be defined in a similar form factor where the tubing inner diameter is continued through the tee body and interfaces with the slot opening 507 to the cover plate manifold. An insert 508 (FIG. 5D), that can provide flow control/distribution in a parallel flow configuration, can be defined that is shaped 509 (FIG. 5e) to fit into the slot opening of the fitting (507). Flow restrictions (510) are defined in the insert body to achieve the flow control objective with an opening below (511) that admits flow into the evaporator manifold. The use of an insert body during the assembly of the cold plate loop allows the precise definition of the flow restriction required to balance the flow in a configuration/layout determined/dictated by the server architecture.

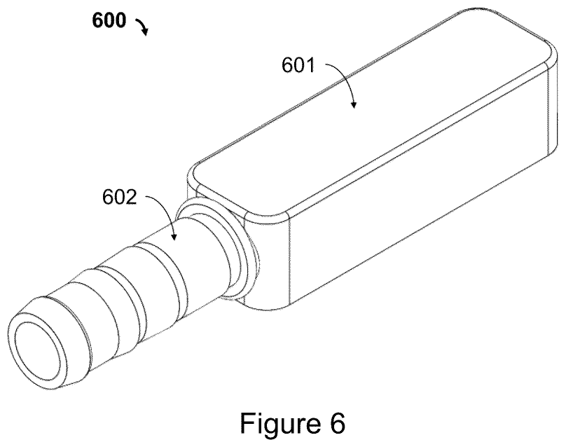

FIG. 6 shows an additional implementation of a low-profile fitting 600 with a barb connection for polymer barrier tubing. The long elbow design (601) incorporates a barb connection (602) that can connect to polymer barrier tubing defining the CPL.

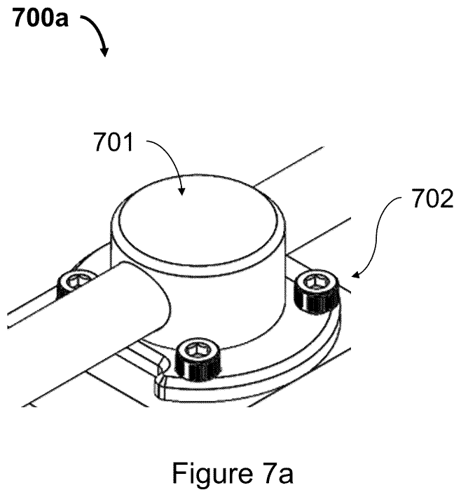

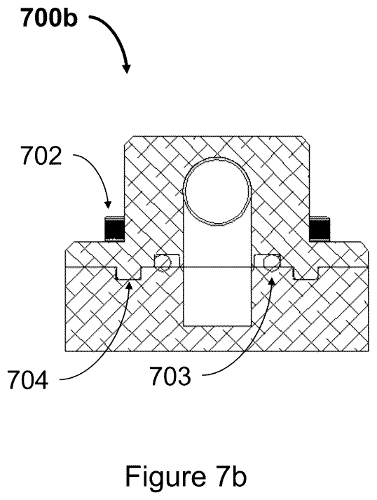

FIG. 7a shows an additional implementation of the CPL fitting 700 to fluidically couple to the cold plate. The fitting 701 is implemented with mechanical attachment 702 such as machine screws and a combination of O-ring 703 and epoxy sealing of a tongue and groove joint design 704. FIG. 7b is a cross-sectional view of FIG. 7a.

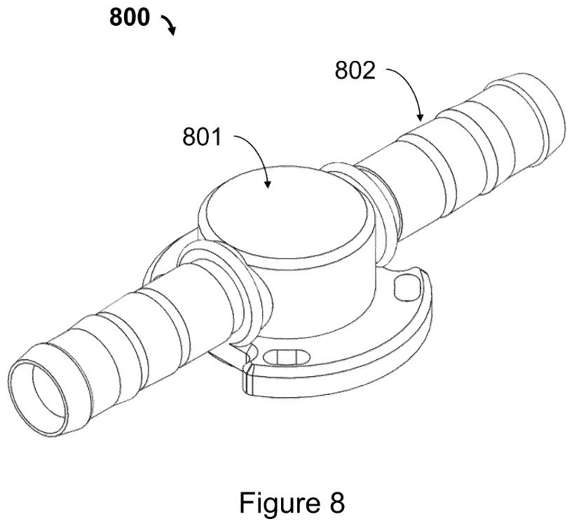

FIG. 8 shows an additional implementation of the CPL fitting 800 with barb connections. The fitting body 801 implemented with mechanical attachment as described in FIG. 7 incorporates a barb connection 802 that interfaces to a polymer barrier tube.

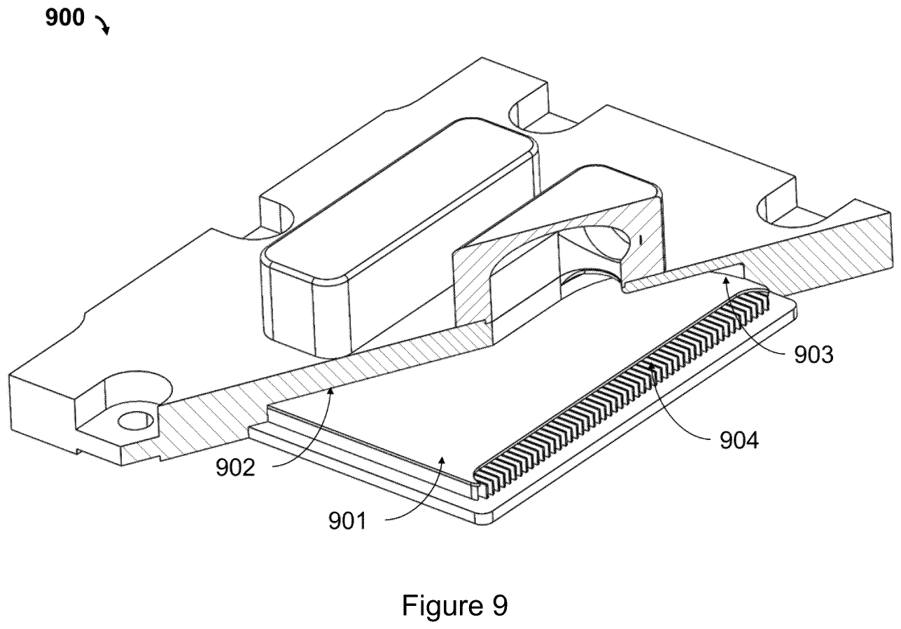

FIG. 9 shows the thin insert sheet 901 for flow separation between the manifolds and heat transfer section as well as flow distribution control. The insert is interposed between the base plate and cover plate 902 during the assembly of the evaporator. The evaporator manifolds are defined by cavities defined in the cover plate 903 and bounded by the insert 904. Flow into and out of the heat transfer section is defined by regions of material removed from the insert 904. The thickness of the insert is minimized to increase the available stack up height of the evaporator, but sufficiently thick as not to bow along unsupported spans due to a pressure differential between the heat transfer section and the evaporator manifold and can be structured to provide additional flow guiding functionality.

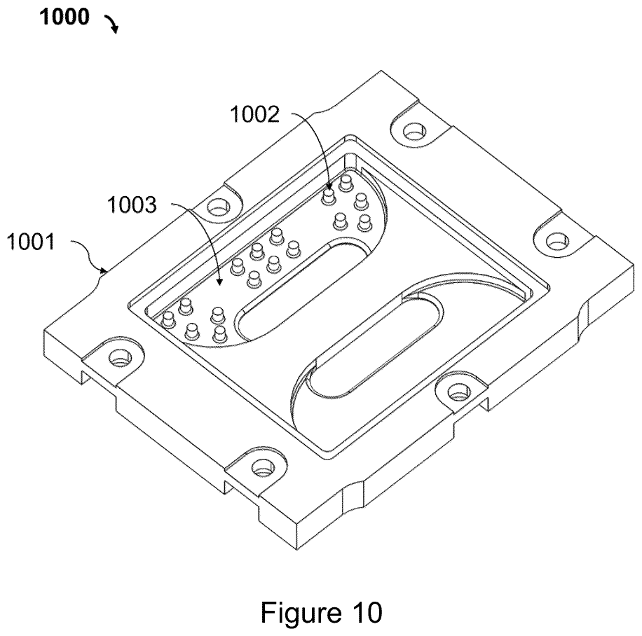

FIG. 10 shows a diagram 1000 of the cover plate 1001 defining the evaporator manifold with flow-guiding pin fins 1002 incorporated to define preferential flow paths 1003 and, hence, the flow distribution to the heat transfer section according to the heat source distribution beneath the evaporator.

A thin sheet insert is provided for as shown in 901, which distributes liquid coolant from the inlet header defined by the cover plate 902, 1001 to the heat transfer structures 904 on the component backside via strategically defined fluid apertures. The geometry of the thin sheet insert (on the order of approximately 0.1 to approximately 1 mm thick) is designed to distribute the flow to the inlet of the heat transfer section and facilitate the flow of vapor to the exit of the evaporator with low pressure drop. The heat transfer structures, e.g., parallel fins, pin fins, porous metal foams, etc., defined on a base plate with a thermally optimized base thickness using well-established manufacturing techniques, are interfaced to the thin sheet insert that provides three key functionalities. First, bonding the thin sheet insert to the heat transfer structures can enhance the mechanical integrity of the base plate when subjected to internal fluid pressure. Second, the thin insert sheet defines the distribution of the coolant fluid from/to the manifold to/from the heat transfer structures allowing the heat sink to address power maps specific to the target device and, generally, to optimize the thermofluidic performance of the heat sink. Thirdly, the apertures defined in the insert sheet insert for admitting liquid flow can be sized at capillary length scales to provide a restoring back pressure to mitigate back flow instabilities arising from the nucleation of the vapor phase in the heat transfer structures and allow for flexibly locating the liquid inlets to the heat transfer section.

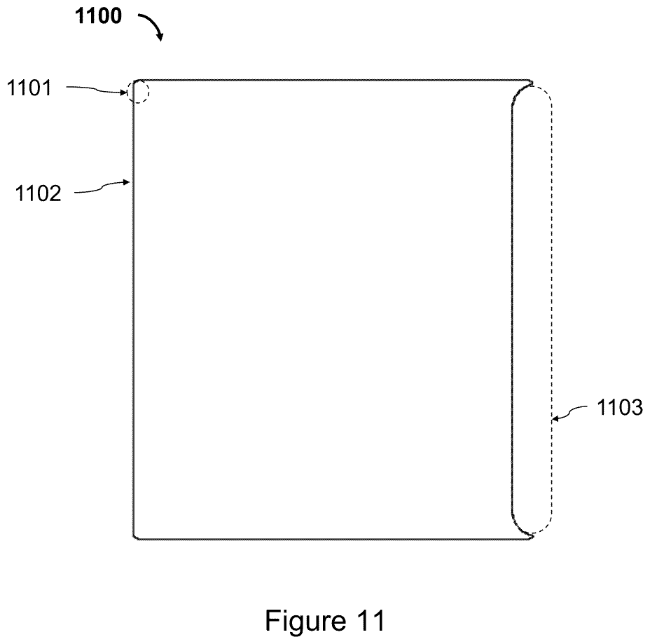

FIG. 11 shows a top view 1100 of an implementation of the thin insert sheet for flow separation between the manifolds and heat transfer section as shown in FIG. 9, 901 as well as flow distribution control. The corners of the insert are radiused 1101 to match the internal radiused corners of the cover plate to facilitate registration of the insert. Restriction openings less than the registration radius 1102 can be defined by removing a rectilinear slice of material from the insert. Restriction openings greater than the registration radius 1103 can be defined by removing a slot of material from the insert to preserve the registration feature.

The liquid inlet opening 1102 is sized to function as an orifice for the liquid flow entering the heat transfer section. This inertial device can alleviate back flow instabilities arising from the generation of the rapidly expanding vapor phase in the heat transfer section when power is applied to the evaporator via the base plate.

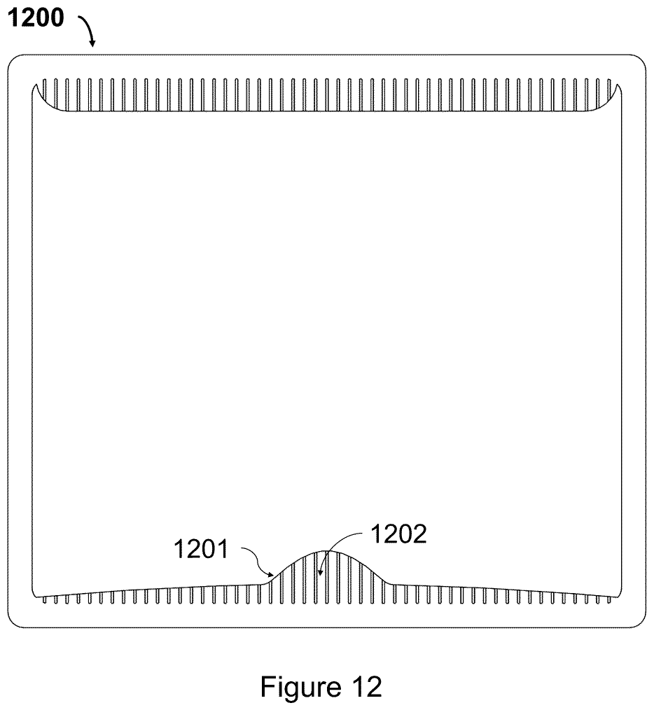

FIG. 12 shows an additional implementation 1200 of the thin sheet insert for flow separation and distribution situated above the heat transfer section 1202. The inlet restriction profile 1201 can be defined to facilitate a non-uniform flow distribution to the heat transfer section that matches the power map of the imposed heat load. This open design is most relevant for an incoming two-phase flow where back flow instability due to the nucleation of the vapor phase is of little or no concern.

It should be noted that an orifice structure located at the liquid inlet(s) to the heat transfer section can bias flow towards the outlet(s) of the heat transfer section but since this is an inertial device, it is most effective when a rapid expanding flow is generated in the heat transfer section due to the ongoing process of nucleation. If the onset of boiling is gentle or if the thermal power input to the heat transfer section is relatively low, the biasing effect of the orifice can be reduced to the point where the vapor phase can flow back through the orifice into the liquid manifold and onwards to the liquid supply line. This situation can disrupt the stability of the overall cooling loop at start-up or during operation by reducing the effective density difference between the vertically arranged two-phase return line and the nominal single phase supply line which is responsible for generating the distributed pumping action in a gravitationally driven passive two-phase cooling loop.

This issue can be mitigated by replacing the orifice structure with a liquid inlet comprised of liquid wetting apertures with characteristic dimensions below the capillary length scale, l_{c}≤\sqrt{γ/(Δμg)}, where γ is the fluid surface tension, Δρ is the density difference between the liquid and vapor phases of the fluid, and g is the gravitational acceleration constant. Rather than relying on inertial forces to bias the flow towards the outlet(s) of the heat transfer section, capillary forces are leveraged to generate a back pressure when the vapor phase wets the apertures given by Δp_{c}=2γ cos θ/R, where γ is the fluid surface tension, θ is the contact angle of the liquid on the solid material comprising the apertures, and R is the liquid/vapor interface curvature radius defined by the characteristic dimension of the apertures, e.g. one-half a hole diameter. This instability suppressing mechanism is operative even at zero flow conditions and functions as a phase selective check valve whereby liquid can readily pass but vapor cannot when θ≤90° and the pressure difference across the apertures is <Δp_{c}.

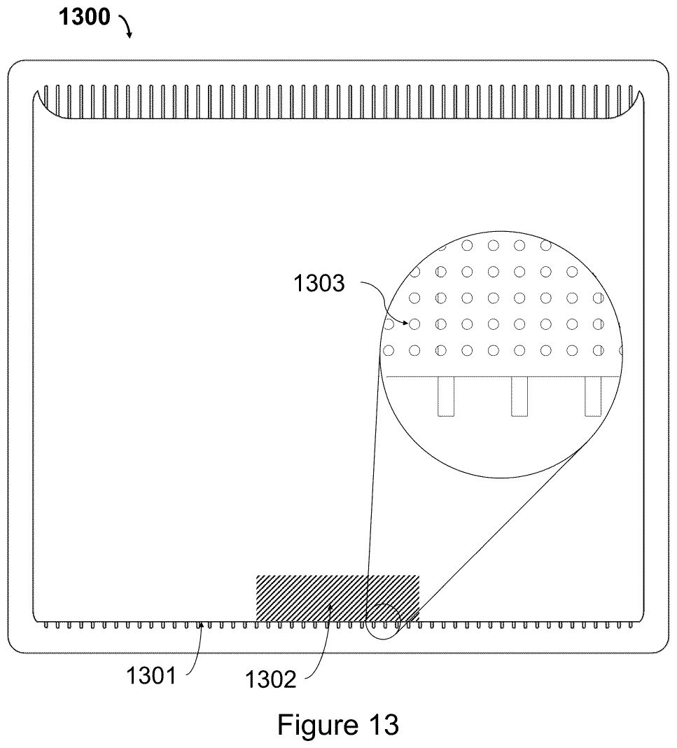

FIG. 13 shows an implementation 1300 of the thin sheet insert for flow separation and distribution incorporating capillary-scale apertures. The inlet restriction 1301 is complimented by an array of small apertures in the insert 1302 that can be, for example holes 1303 that are sized approximately at or below the capillary length, l_{c}. Such features can facilitate a non-uniform flow distribution to the heat transfer section that matches the power map of the imposed heat load while avoiding the back flow of the vapor phase from the heat transfer section into the liquid manifold. This design is most relevant for an incoming single-phase liquid flow where back flow instability due to the nucleation of the vapor phase is a concern.

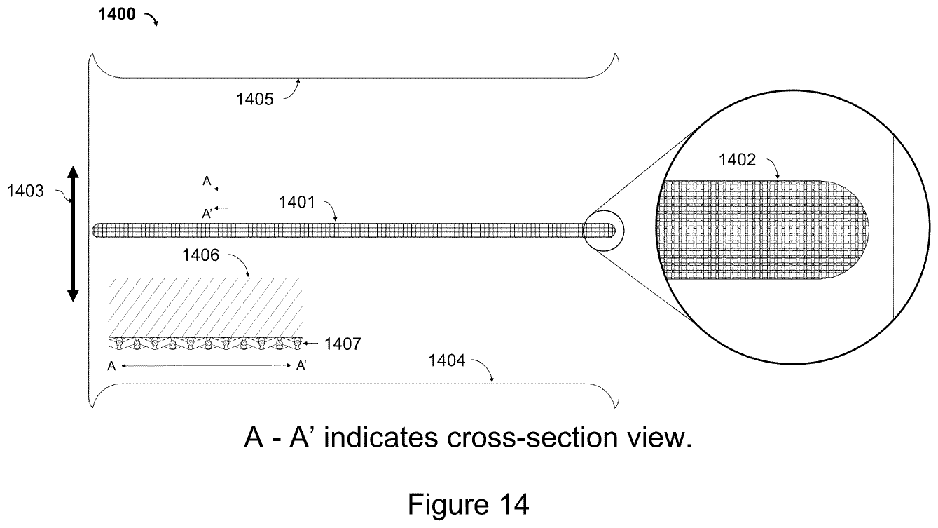

FIG. 14 shows an alternative implementation 1400 of a thin sheet insert for flow separation and distribution having a composite dense/porous structure with a centralized porous inlet 1401 comprised of a fine mesh structure 1402 providing for bidirectional flow 1403 in the heat transfer section to a first outlet 1404 and a second outlet 1405. The composite thin sheet insert can be a layered structure of dense material 1406 bonded to a fine mesh sheet 1407.

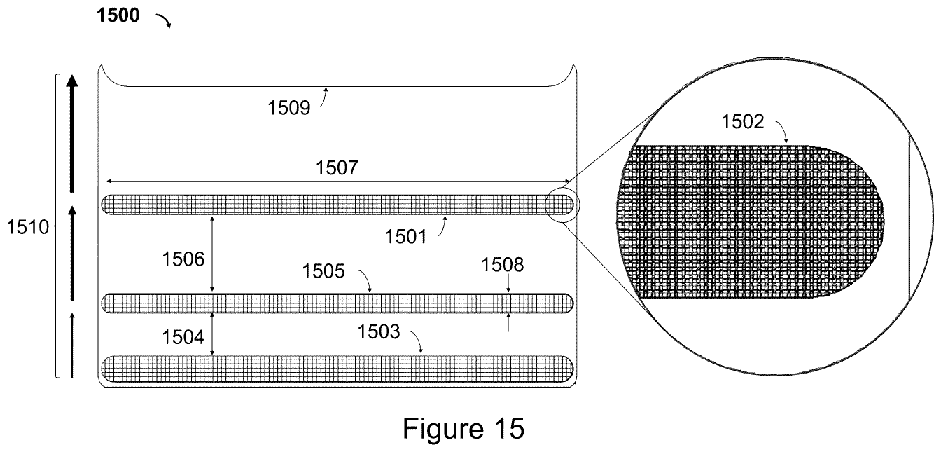

FIG. 15 shows an additional implementation of a composite dense/porous, thin sheet insert for flow separation and distribution with distributed porous inlets 1501 with small scale flow apertures 1502 providing for the injection of liquid flow along the flow path in the heat transfer section. A first flow inlet 1503 is separated by a distance 1504 from a second flow inlet 1505 that may have a different opening width 1508 relative to the first flow inlet. Subsequent flow inlets 1501 along the primary flow direction 1510 may have a different separation distance 1506 and the widths 1507 of the openings may vary according to the distribution of heat loads beneath the heat transfer section. The exit from the heat transfer section through the thin sheet insert 1509 is devoid of porous structures to facilitate the easy removal of the two-phase flow 1510 from the heat transfer region into the evaporator manifold.

To highlight the efficacy of a distributed inlet design, simulation results are provided.

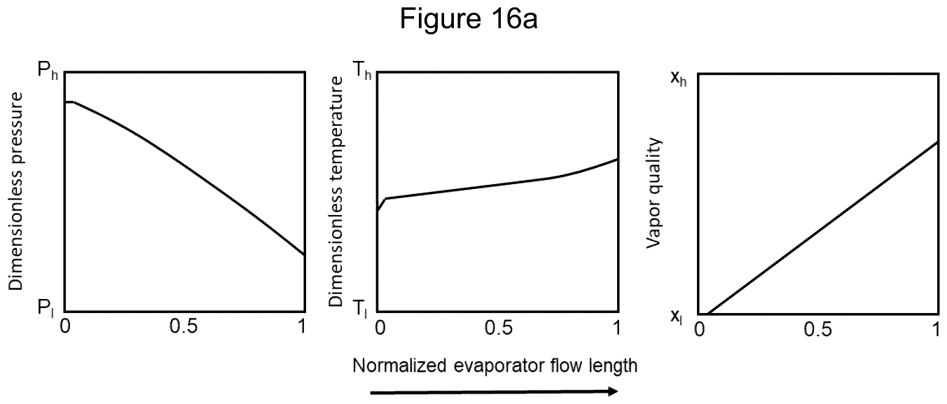

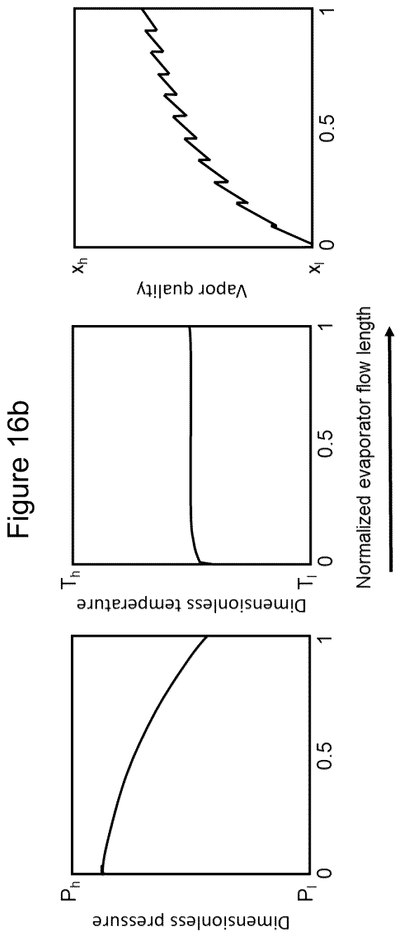

FIG. 16a shows evaporator simulation results of dimensionless pressure drop, dimensionless base temperature variation and flow quality along the flow direction in the heat transfer section for a single liquid inlet design.

FIG. 16b shows corresponding evaporator simulation results for a distributed liquid inlet design similar to that shown in FIG. 15.

Both simulation results consider the heat transfer section subject to identical uniform heat load and exit mass flow rate. The exit flow quality from both evaporator designs is the same (same total mass flow rate at the exit of the two evaporator and heat dissipated).

For a single inlet liquid flow, the mass flux is constant along the flow direction in the heat transfer region and pressure drop is non-linear due to the linearly increasing flow quality. It is also observed that the evaporator base temperature increases along the flow direction. In the situation where the liquid inlet flow is distributed along the heat transfer section.

We observe that the pressure drop can be reduced by limiting the local mass flux which increases to its maximum only near the exit of the heat transfer section. Correspondingly, the flow quality increases more rapidly in a stepwise fashion near the start of the heat transfer region and becomes flatter near the exit of the heat transfer region. The result is that the evaporator base temperature can be maintained at a lower and almost constant value compared to the single inlet design.

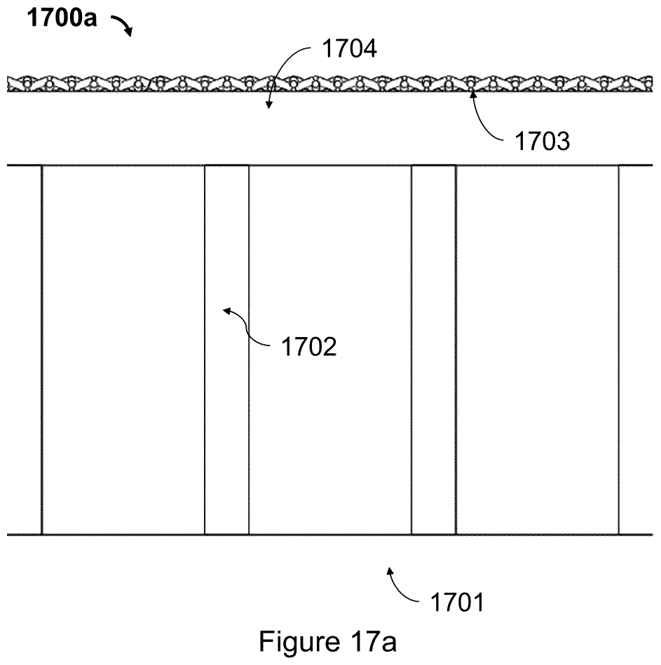

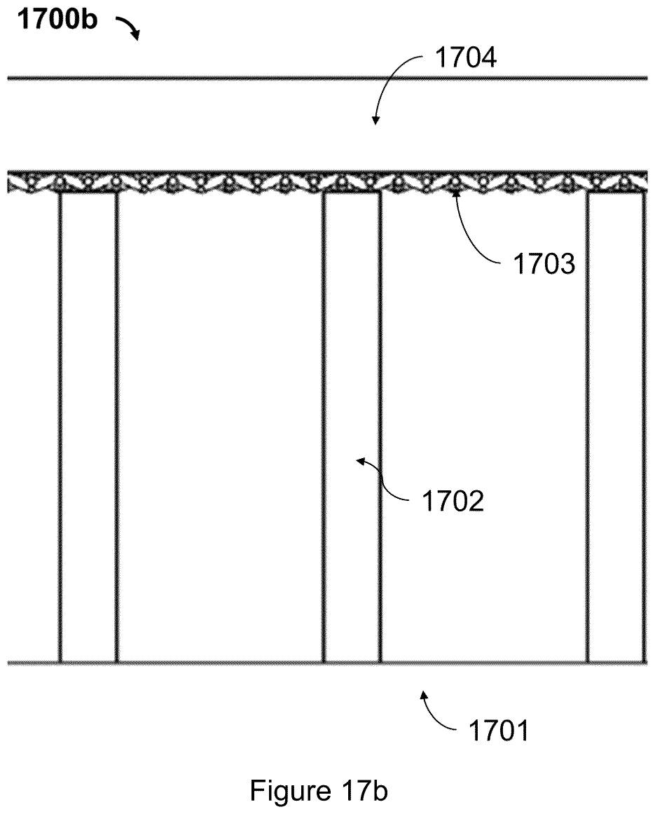

FIG. 17a shows a schematic of the porous-layer-up configuration 1700a for the composite dense/porous, thin sheet insert interfacing to the transfer section of the evaporator introduced in FIG. 15.

FIG. 17b is a schematic of the porous-layer-down configuration 1700b for the composite dense/porous, thin sheet insert interfacing to the heat transfer section of the evaporator introduced in FIG. 15.

FIGS. 17a and 17b show schematics of two configurations 1700a and 1700b for the composite thin sheet insert interfacing to the heat transfer section of the evaporator. The capillary scale porous structures, e.g., a woven mesh, 1703 may be sintered or otherwise bonded to the dense portion of the insert 1704 that can contain a number of larger openings such that fluid can pass through the insert via the openings of the porous portion of the composite thin sheet insert as described in FIGS. 14 and 15.

Referring to FIG. 17a, the insert can be installed such that the dense portion of the insert 1704 is in contact with the heat transfer structures 1702 disposed on the evaporator plate 1701. This has the advantage of presenting a substantially smooth surface to the flowing fluid in the heat transfer structures and may present as a more facile interface for bonding the composite thin sheet insert to the heat transfer structures.

Alternatively, as shown in FIG. 17b, the insert can be installed such that the porous portion is in contact with the heat transfer structures 1702 disposed on the evaporator base (1701). This has the advantage of providing a capillary bridge to capillary structures that may be defined on the surface of the heat transfer structures.

Additional optimization of the thermohydraulic characteristics of the CPL can be achieved by introducing surface structuring in the heat transfer section of the evaporator 1202 at length scales smaller than the extended surface structures 1702 comprising the heat transfer section.

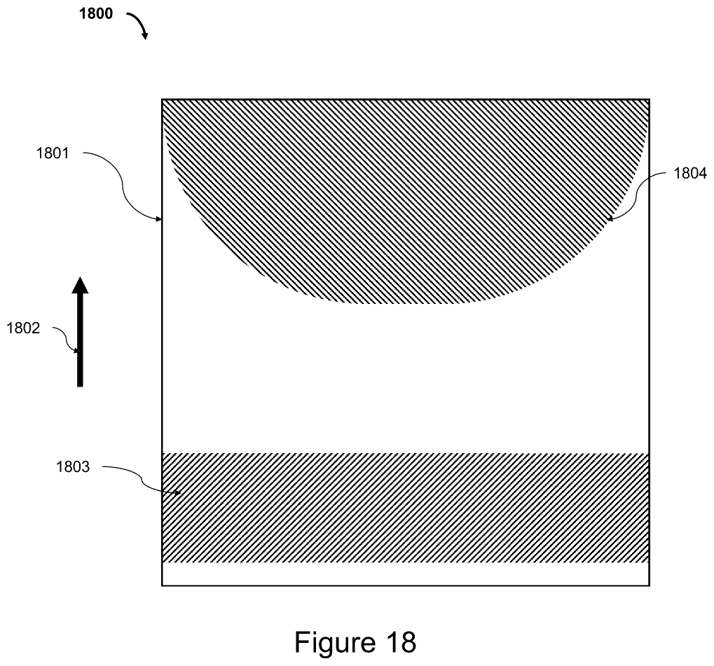

FIG. 18 shows a top-view schematic 1800 of the spatial distribution of surface roughness enhancement in the heat transfer section. The spatial extent defining the heat transfer section 1801 can be comprised of fins, pins or other extended surface structures that transfer heat to the flow passing from the inlet to the outlet 1802.

The surface of the extended surface structures are roughened at a length scale smaller than the characteristic length scale of the extended surface structures, e.g., μm vs. mm, by mechanical, optical, chemical means or a combination of techniques to spatially control and enhance the nucleation rate of the vapor phase in the inlet section of the heat transfer section 1803 when the flow quality is x˜0 and the liquid may be sub-cooled.

This is particularly important for serial flow CPL configurations where the single-phase flow length for the first evaporator must be minimized and to rapidly transition through the slug flow regime to maintain an overall low thermal resistance and stability for the evaporator. Where the flow quality is x>0 in the heat transfer section, the structured region 1804 is now optimized to provide a capillary wicking path for the working fluid to avoid degradation in evaporator thermal performance due to the onset of local dry-out within the heat transfer section that can occur towards the outlet of the heat transfer section or in subsequent evaporators in a serial flow CPL configuration.

The characteristics of the surface roughness can be tuned independently to achieve, for example, optimized nucleation enhancement and/or an optimized low-pressure loss liquid wicking path to prevent local dry-out of the extended surface structures

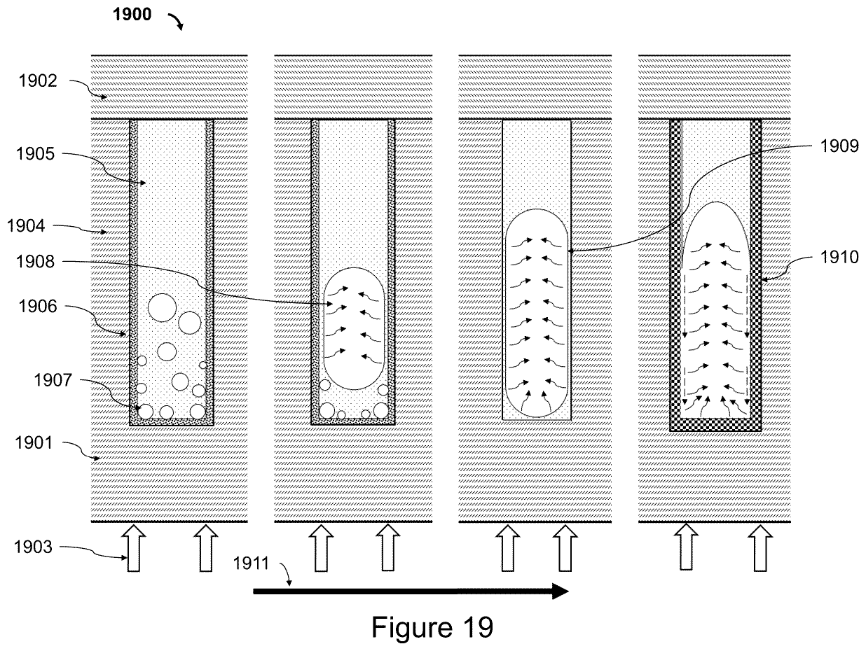

FIG. 19 shows a cross-section schematic 1900 of the evolving two-phase flow in the spatially distributed surface roughness enhanced heat transfer section associated with FIG. 18.

The heat transfer section 1901 is comprised of fins, pins or other extended surface structures 1904 with a characteristic length scale of approximately ˜0.1-approximately 1 mm that are capped by the thin sheet insert 1902 to contain the working fluid 1905 on one side and subject to an imposed heat load 1903 on the other side. To improve the overall operation of the CPL, the surface of the extended surface structures may be roughened 1906 uniformly or non-uniformly along the fluid flow direction 1911 and accounting for the distribution of imposed heat flux by mechanical, optical, chemical, electrochemical means or a combination thereof.

At the inlet to the heat transfer section, the primary goal is to enhance the nucleation rate of the vapor phase 1907 from the liquid phase of the working fluid that may be sub-cooled to promote better heat transfer performance at low flow qualities and rapidly transition through the slug flow regime 1908 to the annular flow regime 1909. Enhancing the nucleation rate can be achieved with a relatively thin layer of small-scale roughness (approximately ˜0.01-approximately 10 μm).

In the region of the heat transfer section where a stable annular flow regime has been established (1909), heat conduction across the thin liquid film and evaporation at the liquid/vapor meniscus is the dominant heat transfer mechanism and it can be advantageous to have a smooth surface. However, as the flow quality increases, the risk of local dry-out increases and a porous surface layer may be formed, optimized to provide a liquid wicking path 1910 facilitating the transport of the liquid-phase via capillary action towards the heat input location of the heat transfer section where local dry-out of the liquid phase is likely to initiate.

A relatively thicker layer of larger scale roughness (approximately 1-approximately 100 μm) is preferred to balance the trade-off between capillary pressure generation providing the driving force for flow through the porous region and the viscous losses of the liquid flowing through the porous region.

Incorporating the preceding elements described, we can now define the layout of the CPL in preferential configurations.

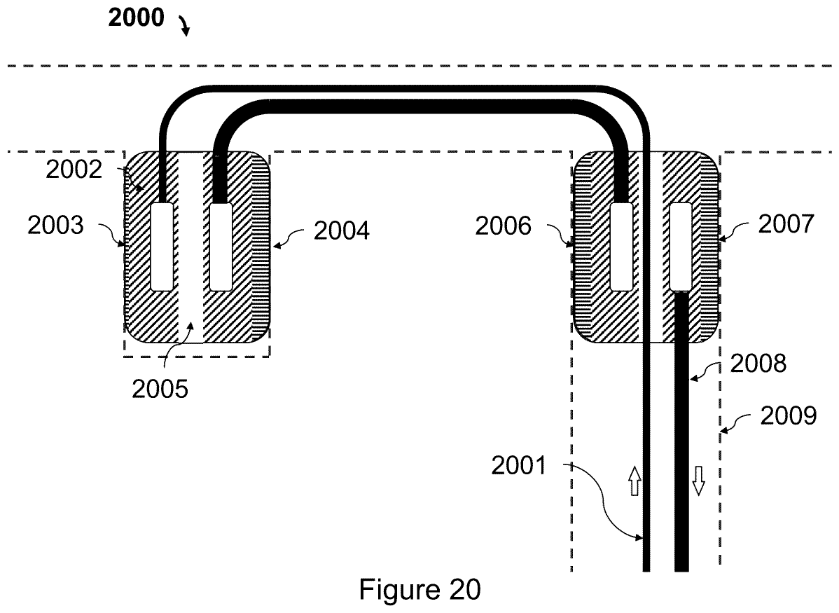

FIG. 20 shows a schematic 2000 of a serial CPL configuration. The working fluid enters the server 2001 in liquid-phase and is routed first to the evaporator furthest from the server inlet. This ensures the shortest two-phase flow return length to the server exit to minimize the overall CPL pressure drop. Liquid flow entering the evaporator is guided by the manifold defined by the cover plate and the insert 2002 to the inlet of the heat transfer section through a restriction 2003 defined by the insert as discussed above.

This restriction serves two primary functions; it helps to distribute fluid to the heat transfer section and provides a biasing to prevent back flow due to the nucleation of the vapor phase at the inlet of the heat transfer section. As the working fluid passes through the heat transfer section, it undergoes a change of phase leading to a reduction in the fluid's mean density and increase in flow quality.

This expanding/accelerating flow exits the heat transfer section through a larger insert-defined opening 2004 relative to the inlet side to minimize pressure drop. The flow transitions from the outlet manifold, that is separated from the inlet manifold by a divider in the cover plate 2005, via the slotted port. The two-phase flow is routed to the next closest evaporator via a conduit sized similar to or larger than the liquid supply line. The entrance to the heat transfer section 2006 is expanded relative to the inlet of the first evaporator to minimize pressure drop associated with the flow in two-phase. The flow further accelerates and increases in flow quality as it passes through subsequent evaporators and exits through a large opening 2007 to the manifold to minimize pressure drop. The two-phase flow exits the server with a quality x≤1 2008. The overall layout is primarily dictated by keep out regions 2009 inside the space-constrained server volume.

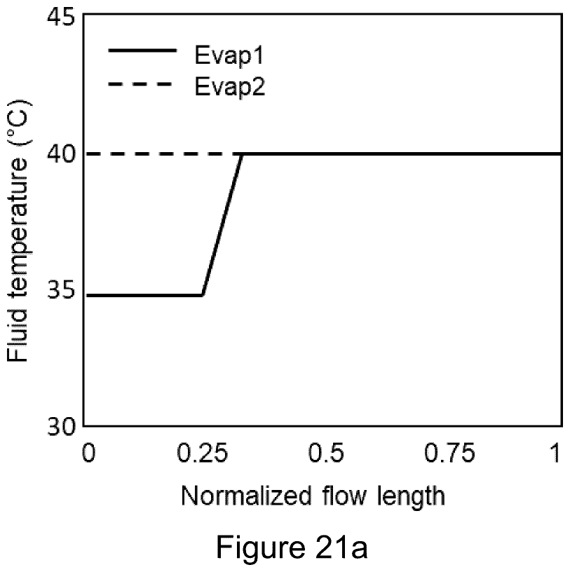

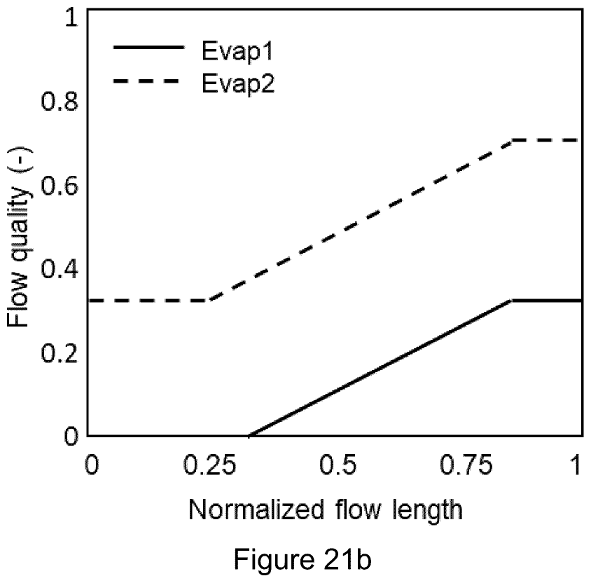

FIGS. 21a and 21b shows simulation results for a serial CPL based on the layout shown in FIG. 20 with two evaporators. As shown in FIG. 21a, we consider a coolant entering the cold plate loop at a saturation temperature of Tₛₐₜ=40° C. and a subcooling of 5 K, where subcooling refers to the temperature difference between the liquid and its saturation temperature at the local pressure. The connecting tubing are asymmetrically sized with an inner diameter ratio of the two-phase tubing to the liquid phase tubing of greater than 1. Both evaporators are subject to the maximum heat load, e.g., TDP, associated with the target processor. In this condition, the design allows for the appropriate operation of the CPL in terms of flow qualities (FIG. 21b) being <1 before the two phase flow leaves the heat transfer region of the CPL. Additional simulations demonstrate that the CPL pressure drop is approximately 50% less compared to the case where the inlet to the second evaporator heat transfer section is not enlarged.

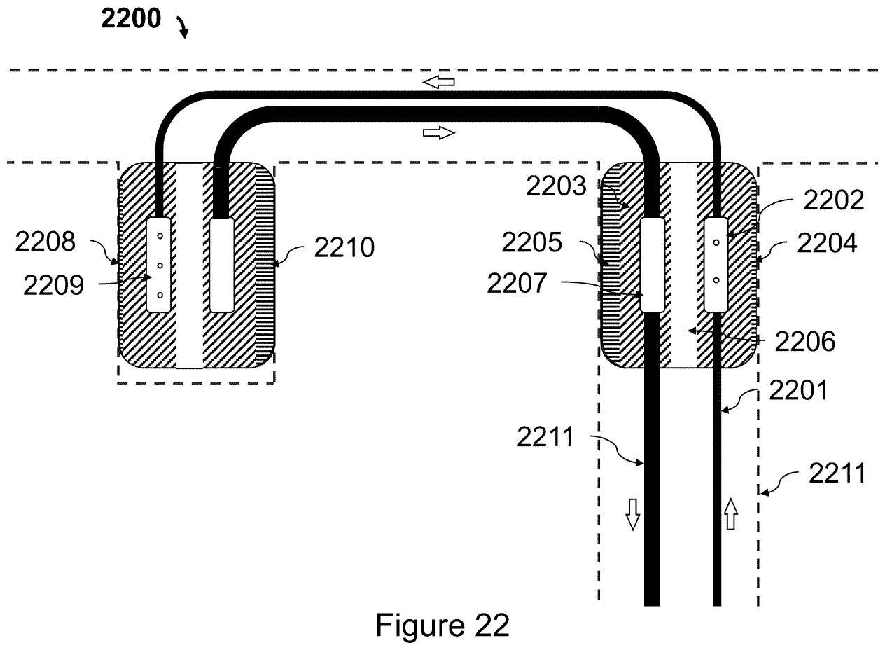

FIG. 22 shows a schematic 2200 of a parallel CPL configuration with two evaporators. The working fluid enters the server 2201 in liquid-phase and is routed to the nearest evaporator where a portion of the flow enters the evaporator metered by an inlet orifice incorporated into a slotted tee fitting 2202.

The reminder of the flow is routed to the second evaporator that is metered by an orifice incorporated into a slotted elbow fitting 2209 that has a hydraulic resistance smaller than the preceding evaporator's orifice. The precise magnitude and ratio of the hydraulic resistances are optimized to facilitate a sufficiently distributed flow to both evaporators even with asymmetric heat loads applied to the two evaporators with the additional goal of minimizing the overall CPL pressure drop.

The internal structure of both evaporators in this flow configuration are nominally the same with an inlet restriction (2204 & 2208) defined by the insert 2203 to promote good flow distribution to the heat transfer section and mitigate back flow instability due to the nucleation of the vapor phase in the heat transfer section inlet. The exit from the heat transfer section is defined by a larger opening (2205 & 2210), relative to the inlet, to minimize the pressure drop of the two-phase flow. The flow transitions from the outlet manifold, that is separated from the inlet manifold by a divider in the cover plate 2206, via the slotted port. Slotted tee 2207 combines the flow from the first and second evaporator onto the return conduit exiting the server 2211.

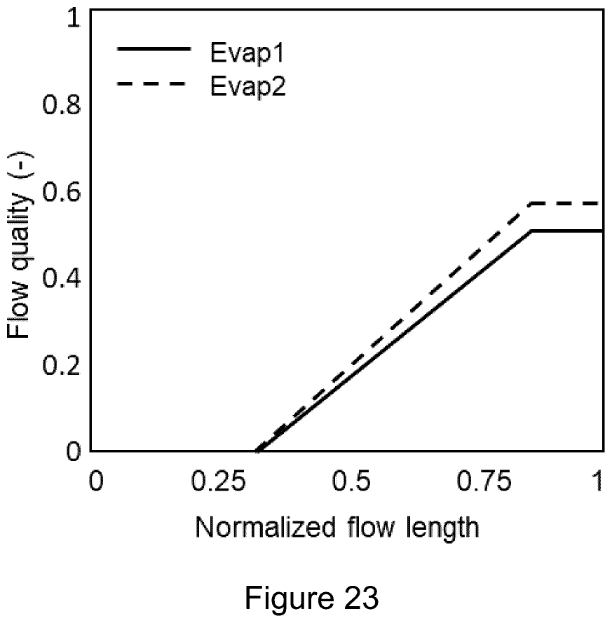

FIG. 23 is a graph showing parallel CPL simulation results based on the layout shown in FIG. 22 with two evaporators.

We consider a coolant entering into the cold plate loop at a saturation temperature of Tₛₐₜ=approximately 30° C. and a subcooling of approximately 5 K. The connecting tubing are asymmetrically sized with an inner diameter ratio of the two-phase tubing to the liquid phase tubing of greater than 1. Both evaporators are subject to the maximum heat load, e.g., TDP, associated with the target processor. Simulations demonstrate that sufficient flow can be routed to both evaporators subject to a symmetric heat load.

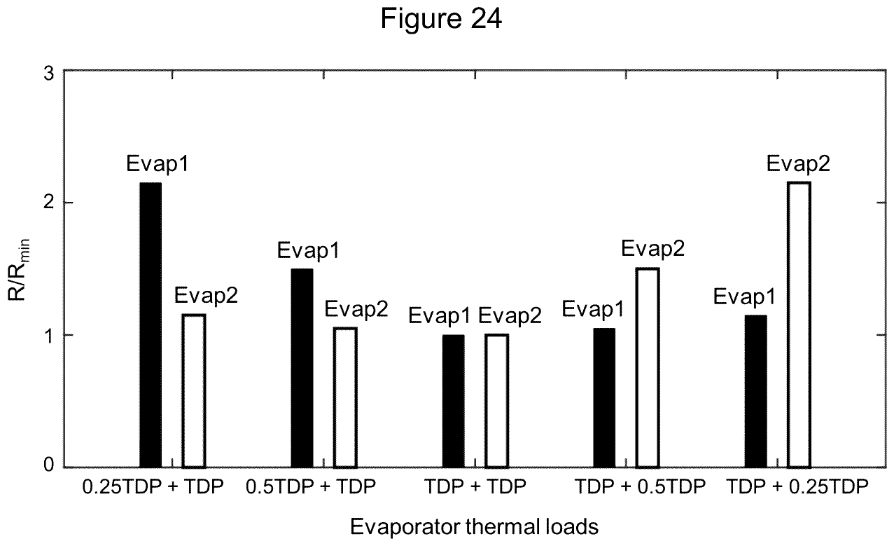

FIG. 24 shows parallel CPL simulation results for asymmetric heat-loading based on the layout shown in FIG. 22. Incorporating the balancing orifices into the slot fittings as discussed in FIGS. 5 and 22 allows for sufficient flow distribution and control to be achieved for heat load diversities of 4x (TDP/0.25TDP, where TDP is the device thermal design power) to maintain the maximum evaporator thermal resistance (R) relative to the minimum thermal resistance (Rₘᵢₙ), R/Rₘᵢₙ≤˜2.

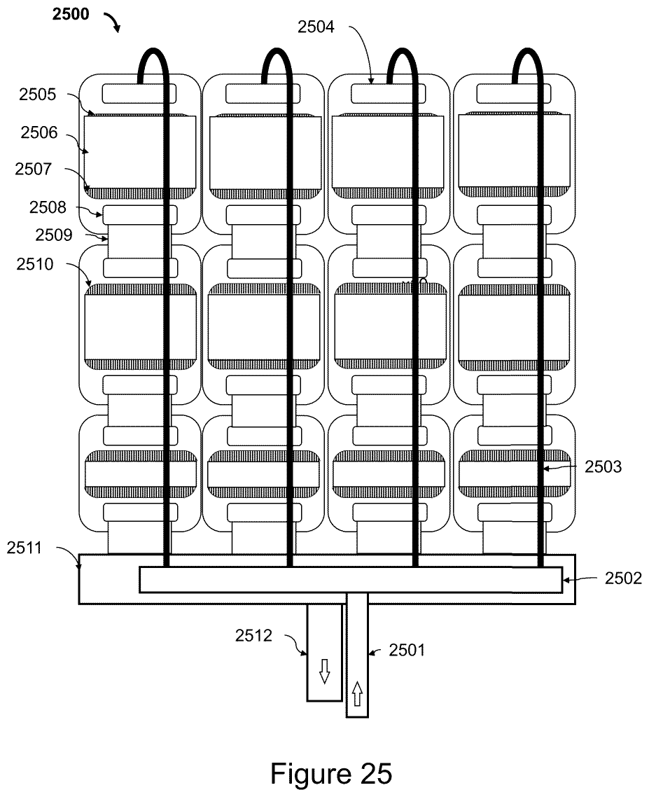

As a further CPL embodiment incorporating layout features in FIGS. 20 and 22, FIG. 25 shows a parallel CPL with nested serial sections with in-server fluid distribution manifolds for a 12-socket server. Liquid-phase flow enters the server via a conduit 2501 and is distributed to four conduits in parallel 2503 via the inlet distribution manifold 2502. The liquid flow is routed to the furthest location from the inlet to minimize the two-phase flow return length and enters the first evaporator of each serial section via a slotted elbow fitting 2504. The first evaporator has an inlet restriction 2505 defined by the insert 2506. The two-phase flow exits the heat transfer section via a larger opening in the insert 2507 to minimize pressure drop and is routed to the next evaporator via an elbow fitting 2508 and a large cross sectional flow area conduit 2509.

Subsequent evaporators on the serial section have large exit openings 2510 from the heat transfer section to minimize pressure drop of the two-phase flow. The serial section terminates at the return collection manifold 2511 sized similar to or larger than the inlet manifold to minimize pressure drop and exits the server through a conduit 2512 sized similar to or larger than the inlet conduit

The term “approximately“ ” approximate” can be +/−10% of the amount referenced. Additionally, preferred amounts and ranges can include the amounts and ranges referenced without the prefix of being approximately.

Although specific advantages have been enumerated above, various embodiments may include some, none, or all of the enumerated advantages.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

To aid the Patent Office and any readers of any patent issued on this application in interpreting the claims appended hereto, applicants wish to note that they do not intend any of the appended claims or claim elements to invoke U.S.C. 112 (f) unless the words “means for” or “step for” are explicitly used in the particular claim.

While the invention has been described, disclosed, illustrated and shown in various terms of certain embodiments or modifications which it has presumed in practice, the scope of the invention is not intended to be, nor should it be deemed to be, limited thereby and such other modifications or embodiments as may be suggested by the teachings herein are particularly reserved especially as they fall within the breadth and scope of the claims here appended.

We claim:

1. An arrangement and internal structure for a two-phase cold plate loop (CPL) designed for cooling an N-component server architecture, where N=1, 2, 3, 4 or more, comprising:
wherein the CPL is deployed in a hardware form factor that minimizes pressure drop while ensuring sufficient flow distribution to achieve thermal performance goals meeting operating temperature requirements for electronic devices;
wherein flow is distributed in serial flow configuration to components to be cooled;
the flow is distributed in parallel flow configuration to the components to be cooled;
wherein the flow is distributed in a combination of serial and parallel flow configurations to the components to be cooled;
wherein CPL architecture is designed specifically to match layout of server components of a server;
wherein CPL evaporators are designed to interface with specific socket architectures of specific server architecture;
wherein the CPL evaporators are designed to dissipate thermal design power (TDP) of heat dissipating components in the server;
wherein the CPL uses a fluid in phase change that increases amount of vapor as it removes heat from hardware components on a motherboard;
wherein working fluid is selected from the group consisting of fluorinated fluids, natural refrigerants, water, ammonia and volatile heat transfer fluid; and
wherein the working fluid is circulated via active or passive two-phase implementations, wherein in a first case, fluid flow circulation is generated by a local pump within the servers or a centralized pump within a coolant distribution unit, and wherein in a second case, the fluid flow circulation is generated by a capillary-driven mechanism or a gravity-driven two-phase forced convection mechanism or a combination of both.

2. The CPL in claim 1 where one or more of CPL tubing conveying fluid are selected from a cross-section selected from the group consisting of a circular cross-section, a non-circular cross section or a combination of both a circular and a non-circular cross-section, in order to facilitate the routing of fluid in a highly space-constrained server architecture.

3. The CPL in claim 1, wherein the evaporators include inlet and outlet manifold ports on evaporator cover plate are defined as slots to maximize flow area in transition from the evaporator manifolds to a connecting tubing in an orientation selected from the group consisting of a vertical orientation, a horizontal orientation, and an intermediate angle orientation, to provide an optimized flow transition to a connecting tubing via slot-shaped, low-profile tees and elbows to minimize pressure drop, where evaporator fittings and tubing forming the CPL in combination with the evaporators are fabricated in aluminum, an aluminum alloy, copper, a copper alloy, steel, or in any advantageous combination thereof and joined by brazing (torch, induction, or furnace), diffusion bonding, laser welding, ultrasonic welding, gas tungsten arc welding or mechanically connected incorporating one or more sealing methods including polymer seals, such as O-rings or gaskets, or structural epoxy in a tongue and groove joint geometry or a combination of both.

4. A Cold plate loop CPL evaporator arrangement, comprising: flow manifolds and heat transfer section comprised of fins, pins, porous metal foam or other extended surface structures are separated by a thin sheet insert shaped to separate and guide the flow between an evaporator manifold and heat transfer section, wherein at least one of the thin sheet insert and the evaporator manifold, incorporate flow guiding fins or other extended surface structures depending on layout of processors to be cooled.

5. The Cold plate loop CPL evaporator arrangement of claim 4, wherein the thin sheet insert has variable shapes towards inlet and outlet manifolds to be able to mitigate pressure drops across the evaporators, including inlet and outlet manifolds, as well as heat transfer section, and wherein shaping of the inlet defined by the insert to the heat transfer section has a profile or additional openings that tailor distribution of flow to address power map of a heat source.

6. The Cold plate loop CPL evaporator arrangement of claim 4, wherein the thin sheet insert includes apertures that separates one or more heat transfer sections from two or more fluid manifold sections to optimize mechanical integrity and thermofluidic performance while mitigating flow instabilities associated with nucleation in the heat transfer section and biasing the flow towards the outlet manifold.

7. The Cold plate loop CPL evaporator arrangement of claim 6, where a sheet element is mechanically bonded to a top of the heat transfer section to mechanically reinforce heat sink subject to internal pressure by means selected from the group consisting of laser welding, diffusion bonding, adhesively, brazing, and soldering

8. The Cold plate loop CPL evaporator arrangement of claim 6, where the sheet element is disposed with fluid apertures of different sizes and placement locations to guide distribution of liquid from the inlet manifolds to the heat transfer section and removal of the two-phase flow from the heat transfer structures to the outlet manifolds based on power map of the processors targeted for cooling.

9. The Cold plate loop CPL evaporator arrangement of claim 6, where the apertures of the sheet element associated with the distribution of the liquid are sized approximately at or below the capillary length, l_{c}, defined by l_{c}≤\sqrt{γ/(Δμg)}, where γ is the fluids surface tension, Δρ is the density difference between the fluid's liquid and vapor phases, and g is the gravitational acceleration constant, wherein the apertures of the sheet element associated with the removal of the two-phase fluid from the heat transfer section are sized approximately at or above the capillary length defined by l_{c}≥\sqrt{γ/(Δμg)}, where γ is the fluids surface tension, Δρ is the density difference between the fluid's liquid and vapor phases, and g is the gravitational acceleration constant.

10. A two-phase heat sink comprising:
one or more liquid distribution manifolds interposed between a sheet element and one or more two-phase distribution manifolds substantially in thermal contact via conduction to reduce a degree of liquid subcooling before entering a heat transfer section from a liquid distribution manifold

11. The two-phase heat sink of claim 10, where the at least one liquid distribution manifold forms an insert inside a heat sink that mechanically aligns with the sheet element to substantially isolate fluid in liquid manifold volume from fluid in the two-phase manifold volume.

12. The two-phase heat sink of claim 10, wherein two-phase distribution manifolds are defined in part by an upper cover plate bonded to a lower base plate

13. The two-phase heat sink of claim 10, wherein a cover plate interface to the liquid distribution manifold incorporates a valve whose flow characteristics respond to pressure drop across the valve via a fluid-structure interaction mechanism to throttle maximum mass flow rate (m) of liquid into the heat sink to a pre-determined design value determined by an energy balance and given by \dot{m}=TDP/hₗᵥΔx, where TDP is the thermal design power of the cooling target, hₗᵥ is the latent heat of vaporization, and Δx is the targeted change in flow quality through the evaporator.

14. The CPL in claim 1, wherein a heat transfer section is comprised of fins, pins or other extended surface structures that are capped by a thin sheet insert and are roughened by mechanical, optical or chemical means to maximize and spatially control nucleation rate of vapor phase achieved with a relatively thin layer of small-scale roughness (approximately 0.01 to approximately 10 μm) and provide for a surface wicking layer in a region of the evaporator experiencing flow qualities x→1 with a relatively thicker layer of larger scale roughness (approximately 1-approximately 100 μm) to ensure a continuous wetting later of liquid on the heat transfer surface.

15. The CPL in claim 1 wherein server inlet tubing conveying fluid in a liquid phase is routed over evaporators nearest to the fluid entry/exit point into the server to an evaporator furthest from the fluid entry/exit point into the server to minimize the two-phase flow length in a serial flow configuration.

16. The CPL in claim 15, wherein a furthest evaporator has an inlet manifold restriction defined by a thin sheet to distribute the liquid-phase fluid evenly to the heat transfer section and minimize back flow instability due to the nucleation of the vapor phase in the heat transfer section.

17. The CPL in claim 15, wherein the insert on the inlet manifold side to subsequent evaporators is designed to minimize restriction of the two-phase flow into the heat transfer section to minimize pressure drop.

18. The CPL in claim 1, wherein server inlet tubing conveying fluid in liquid phase is routed in a parallel flow configuration to all evaporators, and wherein low-profile fittings incorporate flow control inserts with dissimilar geometries and, hence pressure drop characteristics defined to balance flow distribution between the multiple evaporators under symmetric and asymmetric heat loads; wherein all evaporators have an inlet manifold restriction defined by a thin sheet to distribute the liquid-phase fluid evenly to the heat transfer section and minimize back flow instability due to the nucleation of the vapor phase.

19. The CPL in claim 1, further comprises:
a modular manifold located near fluid entry/exit point into the server, which is designed to equally route the liquid phase to the inlets of all evaporators and receive a two-phase mixture to the outlet of all evaporators, and the modular manifold comprises multiple sections depending on number of processors and thus CPL evaporators to be cooled in parallel or parallel banks of evaporators that are cooled in series.

20. The CPL of claim 1, wherein the evaporators comprise an extended surface to remove heat from secondary side components that include voltage regulators, via conduction or convection heat transfer mechanism, wherein CPL evaporators are oriented in a way that flow is pre-heated due to the heat removal from the secondary side components to be able to maximize thermal performance in an effective heat transfer area as there is a shorter liquid phase heat transfer length.
